(19) United States
(12) Patent Application Publication
(10) Pub. No.: US 2026/0068497 A1
(43) Pub. Date: Mar. 5, 2026

(54) DISPLAY PANEL, METHOD FOR PREPARING DISPLAY PANEL, AND ELECTRONIC DEVICE

(71) Applicants: Visionox Technology Inc., Kunshan (CN); Hefei Visionox Technology Co., Ltd., Hefei (CN)

(72) Inventors: Fengying XU, Kunshan (CN); Yuan YAO, Hefei (CN); Aihua XUE, Kunshan (CN); Manli CHEN, Hefei (CN); Tian WANG, Hefei (CN)

(73) Assignees: Visionox Technology Inc., Kunshan (CN); Hefei Visionox Technology Co., Ltd., Hefei (CN)

(21) Appl. No.: 19/315,661

(22) Filed: Sep. 1, 2025

(30) Foreign Application Priority Data
Sep. 2, 2024 (CN) 202411216140.2

(51) Int. Cl. H10K 59/80; H10K 59/122

(52) U.S. Cl. CPC H10K 59/873; H10K 59/122

(57) ABSTRACT

Embodiments of the present application relate to the field of displays, and provide a display panel, a method for preparing a display panel, and an electronic device, the display panel including a first active area and a second active area at least partially surrounding the first active area, and the display panel including an array substrate, an isolation structure and a first encapsulation layer. At least part of the isolation structure encloses first openings, the first encapsulation layer at least partially fills each of the first openings and is in contact with a side of the at least part of the isolation structure close to each of the first openings, the first encapsulation layer includes a first embedded structure, and the first embedded structure is located in the first opening and is in contact with the isolation structure.

### CROSS REFERENCE TO RELATED APPLICATION

This application claims priority to Chinese Patent Application No. 202411216140.2, entitled “DISPLAY PANEL, METHOD FOR PREPARING DISPLAY PANEL, AND ELECTRONIC DEVICE” and filed on Sep. 2, 2024, which is hereby incorporated by reference in its entirety.

### FIELD

The present application relates to the field of display, and in particular to a display panel, a method for preparing a display panel, and an electronic device.

### BACKGROUND

Organic light emitting diodes (OLEDs) and flat panel display devices based on technologies such as light emitting diodes (LEDs) have been widely applied to various consumer electronics such as mobile phones, televisions, notebook computers and desktop computers and predominate in display panels thanks to their advantages such as high image quality, energy efficiency, slim design and a wide range of applications.

However, the display panels still have some issues that need to be urgently addressed.

### SUMMARY

In order to overcome the problems mentioned in the above background art, embodiments of the present application provide a display panel. The display panel includes:
an array substrate;
an isolation structure located on one side of the array substrate, at least part of the isolation structure enclosing first openings; and
a first encapsulation layer at least partially filling each of the first openings and being in contact with a side of the at least part of the isolation structure close to each of the first openings, the first encapsulation layer including a first embedded structure, and the first embedded structure being located in the first opening and being in contact with the isolation structure.

In a display panel, a method for preparing a display panel, and an electronic device provided by the present application, a first encapsulation layer is configured to include a first embedded structure, and the first embedded structure is located in a first opening and is in contact with an isolation structure, which can increase the adhesion between the first encapsulation layer and the isolation structure and thus the stability of the first encapsulation layer, and in turn can improve the quality of the display panel.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope.

FIG. 1 is a schematic top view of a display panel according to an embodiment of the present application;

FIG. 2 is a schematic enlarged view of a first active area according to an embodiment of the present application;

FIG. 3 is a first schematic cross-sectional view of FIG. 2 taken along line A-A according to an embodiment of the present application;

FIG. 4 is a second schematic cross-sectional view of FIG. 2 taken along line A-A according to an embodiment of the present application;

FIG. 5 is a first schematic cross-sectional view of a first embedded structure according to an embodiment of the present application that is integrally formed with a base;

FIG. 6 is a third schematic cross-sectional view of FIG. 2 taken along line A-A according to an embodiment of the present application;

FIG. 7 is a second schematic cross-sectional view of a first embedded structure according to an embodiment of the present application that is integrally formed with a base;

FIG. 8 is a fourth schematic cross-sectional view of FIG. 2 taken along line A-A according to an embodiment of the present application;

FIG. 9 is a schematic top view of an isolation structure in a second active area according to an embodiment of the present application;

FIG. 10 is a schematic cross-sectional view of a first embedded structure and a second embedded structure according to an embodiment of the present application that are integrally formed with a base;

FIG. 11 is a schematic cross-sectional view of isolation openings of a display panel according to an embodiment of the present application that include a first isolation opening and a second isolation opening;

FIG. 12 is a schematic cross-sectional view of isolation openings of a display panel according to an embodiment of the present application that further include a third isolation opening;

FIG. 13 is a first schematic top view of a first pixel opening, a second pixel opening and a third pixel opening of a display panel according to an embodiment of the present application;

FIG. 14 is a first schematic top view of a first isolation opening, a second isolation opening and a third isolation opening of a display panel according to an embodiment of the present application;

FIG. 15 is a second schematic top view of a first pixel opening, a second pixel opening and a third pixel opening of a display panel according to an embodiment of the present application;

FIG. 16 is a second schematic top view of a first isolation opening, a second isolation opening and a third isolation opening of a display panel according to an embodiment of the present application;

FIG. 17 is a schematic cross-sectional view of a display panel according to an embodiment of the present application that includes a first light-transmitting opening, a second light-transmitting opening and a third light-transmitting opening;

FIG. 18 is a first schematic top view of a first light-transmitting opening, a second light-transmitting opening and a third light-transmitting opening of a display panel according to an embodiment of the present application;

FIG. 19 is a second schematic top view of a first light-transmitting opening, a second light-transmitting opening and a third light-transmitting opening of a display panel according to an embodiment of the present application;

FIG. 20 is a schematic flowchart of a method for preparing a display panel according to an embodiment of the present application;

FIG. 21 is a schematic cross-sectional view of a first electrode layer formed on one side of an array substrate according to an embodiment of the present application;

FIG. 22 is a schematic cross-sectional view of a pixel defining material layer formed on a side of the first electrode away from the array substrate according to an embodiment of the present application;

FIG. 23 is a schematic cross-sectional view of an isolation structure material layer formed on a side of the pixel defining material layer away from the array substrate according to an embodiment of the present application;

FIG. 24 is a schematic cross-sectional view of an isolation structure material layer after patterning according to an embodiment of the present application;

FIG. 25 is a schematic cross-sectional view of pixel openings and grooves formed in the pixel defining material layer by a halftone mask according to an embodiment of the present application;

FIG. 26 is a schematic cross-sectional view of a light-emitting functional layer formed in an isolation opening according to an embodiment of the present application;

FIG. 27 is a schematic cross-sectional view of a second electrode layer on a side of the light-emitting functional layer away from the array substrate that is formed in the isolation opening according to an embodiment of the present application; and

FIG. 28 is a schematic cross-sectional view of a second encapsulation layer formed on a side of the second electrode layer away from the array substrate according to an embodiment of the present application.

List of reference signs: 1. Isolation structure; 101. First isolation portion; 102. Second isolation portion; 103. Third isolation portion; 2. Isolation opening; 21. First isolation opening; 22. Second isolation opening; 23. Third isolation opening; 3. First opening; 31. First light-transmitting opening; 32. Second light-transmitting opening; 33. Third light-transmitting opening; 4. Light-emitting unit; 5. Array substrate; 6. Pixel defining layer; 61. Pixel opening; 611. First pixel opening; 612. Second pixel opening; 613. Third pixel opening; 62. Groove; 7. First electrode; 8. Light-emitting portion; 9. Second electrode; 10. First encapsulation layer; 11. Second encapsulation layer; 111. Encapsulation unit; 12. First embedded structure; 121. First embedded portion; 122. First recessed portion; 123. Second recessed portion; 124. Second embedded portion; 125. Third recessed portion; 13. Third encapsulation layer; 14. Pixel defining material layer; 15. Isolation structure material layer; 16. Second embedded structure; 17. Base.

### DETAILED DESCRIPTION OF THE EMBODIMENTS

In order to make the embodiments of the present application clearer, the embodiments of the present application will be described clearly and completely below with reference to the accompanying drawings in the embodiments of the present application. The embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

A display panel in the related art includes an array substrate, an isolation structure on one side of the array substrate, a second encapsulation layer on a side of the isolation structure away from the array substrate, and a first encapsulation layer on a side of the second encapsulation layer and part of the isolation structure away from the array substrate. The inventors have found through long-term research that the stability of the first encapsulation layer is not robust enough and is likely to suffer from problems such as delamination, which eventually affects the quality of the display panel.

In view of this, this embodiment provides a solution by which the reliability of the display panel can be improved, and the solution provided in this embodiment will be elaborated below.

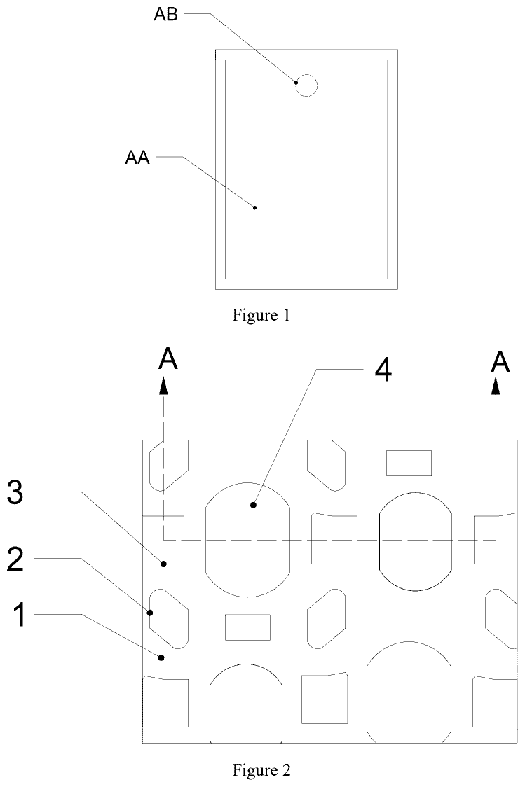

Referring to FIGS. 1-3, this embodiment provides a display panel, which includes an array substrate 5, an isolation structure 1, and a first encapsulation layer 10.

The array substrate 5 may include a substrate and drive units located on one side of the substrate, and each drive unit may include one or more semiconductor switching devices. The semiconductor switching device may be formed collectively by film layers in the array substrate 5. For example, the semiconductor switching device may be a thin film transistor formed collectively by the plurality of film layers.

The isolation structure 1 is located on one side of the array substrate 5, and at least part of the isolation structure 1 encloses first openings 3.

The composition, preparation and other contents of the isolation structure 1 are further described in Chinese Patents Applications No. PCT/CN 2023/134518, 202310759370.2, 202310740412.8, 202310707209.0, 202311346196.5, 202311499823.9, 202310731471.9, 202311091555.7 for reference.

The first encapsulation layer 10 at least partially fills each of the first openings 3 and is in contact with a side of the at least part of the isolation structure 1 close to each of the first openings 3, the first encapsulation layer 10 includes a first embedded structure 12, and the first embedded structure 12 is located in the first opening 3 and is in contact with the isolation structure 1.

The first encapsulation layer 10 may be formed by means of ink-jet printing, and a material of the first encapsulation layer 10 may flow into the first opening 3 and fills the first opening 3. The filling herein may be complete filling of the first opening 3, or there may be a certain void. In one embodiment, the first encapsulation layer 10 completely fills the first opening 3, and the first encapsulation layer 10 filling the first opening 3 forms the first embedded structure 12, and the adhesion between the first encapsulation layer 10 and the isolation structure 1 can be increased. The material of the first encapsulation layer 10 has a high light transmittance, and light can pass through the first opening 3 more easily to a position of a corresponding photosensitive device, thus the display panel can have a better transmittance.

The first encapsulation layer 10 may extend into contact with a side of the isolation structure 1 close to the first opening 3, the first embedded structure 12 located in the first opening 3 is in contact with the isolation structure 1, and the first embedded structure 12 may increase the adhesion between the first encapsulation layer 10 and the isolation structure 1, and it is possible to enhance the stability of the first encapsulation layer 10, and the first encapsulation layer 10 is not likely to suffer from problems such as delamination, which may ultimately improve the quality of the display panel.

Based on the above-described design, in this embodiment, the first encapsulation layer 10 is configured to include the first embedded structure 12, and the first embedded structure 12 is located in the first opening 3 and is in contact with the isolation structure 1, which can increase the adhesion between the first encapsulation layer 10 and the isolation structure 1 and thus the stability of the first encapsulation layer 10, and in turn can improve the quality of the display panel.

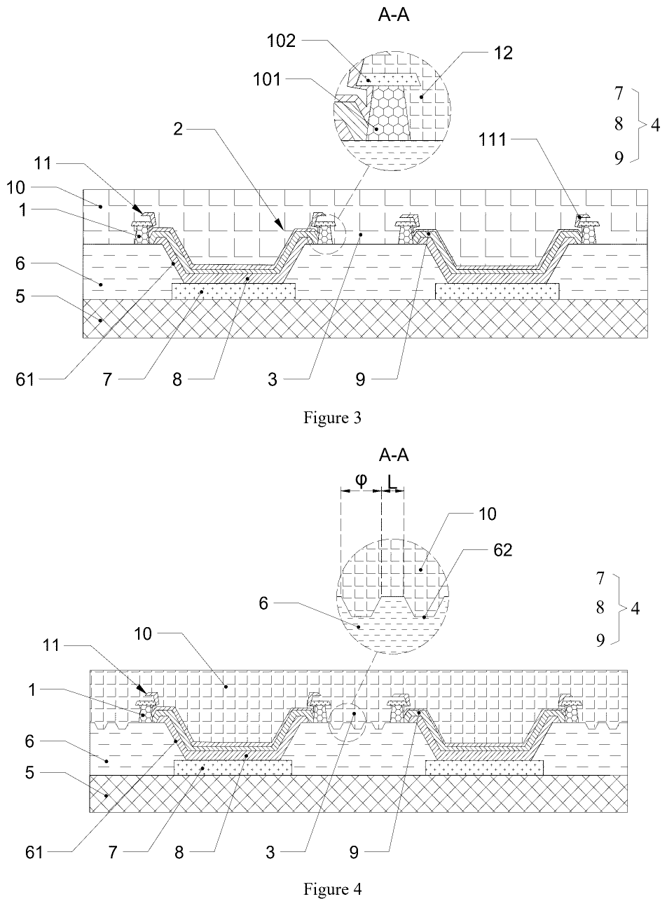

In some embodiments, referring to FIG. 3 again, at least part of the isolation structure 1 encloses isolation openings 2, and a light-emitting unit 4 includes a first electrode 7, a light-emitting portion 8 and a second electrode 9, which are at least partially located in each of the isolation openings 2 and are sequentially stacked in a direction away from the array substrate 5, the second electrode 9 being electrically connected to the isolation structure 1.

When a light-emitting functional layer is formed, the light-emitting functional layer may be separated by the isolation structure 1 to form light-emitting portions 8 arranged at intervals; and when a second electrode layer is formed, the second electrode layer may be separated by the isolation structure 1 to form second electrodes 9 arranged at intervals. The isolation structure 1 includes a conductive material, the second electrode 9 is electrically connected to the isolation structure 1, and one first electrode 7, one light-emitting portion 8 and one second electrode 9 form one light-emitting unit 4. The first electrode 7 is an anode and the second electrode 9 is a cathode.

In one embodiment, referring to FIG. 3 again, an orthographic projection of the isolation opening 2 on the array substrate 5 is located outside an orthographic projection of the first opening 3 on the array substrate 5; and the isolation opening 2 is spaced apart from the first opening 3, and the orthographic projections of the isolation opening 2 and the first opening 3 on the array substrate 5 do not overlap.

In one embodiment, the first encapsulation layer 10 completely fills the first opening 3, and gas is not easily retained in the first opening 3, and the adhesion between the first encapsulation layer 10 and the isolation structure 1 can also be further increased, thus the quality of the display panel can be improved.

In some embodiments, referring to FIG. 3 again, the display panel further includes a second encapsulation layer 11 on a side of the light-emitting unit 4 away from the array substrate 5, the second encapsulation layer 11 including encapsulation units 111, at least part of the encapsulation unit 111 is located in the isolation opening 2 and extends from a side face of the isolation structure 1 facing the isolation opening 2 to a side of the isolation structure 1 away from the array substrate 5, adjacent encapsulation units 111 are spaced apart on the side of the isolation structure 1 away from the array substrate 5, and the encapsulation unit 111 on the side of the isolation structure 1 away from the array substrate 5 has a gap from the side of the isolation structure 1 away from the array substrate 5. In this way, the encapsulation unit 111 may more easily encapsulate the corresponding light-emitting unit 4 completely independently.

In one embodiment, the first encapsulation layer 10 fills the gap, and the first encapsulation layer 10 is more securely engaged with the encapsulation unit 111, thus enhancing the stability of the first encapsulation layer 10.

In some embodiments, referring to FIG. 3 again, the display panel further includes a pixel defining layer 6 on one side of the array substrate 5, the isolation structure 1 is located on a side of the pixel defining layer 6 away from the array substrate 5, the first encapsulation layer 10 filling the first opening 3 is in contact with a side of the pixel defining layer 6 away from the array substrate 5, the pixel defining layer 6 includes pixel openings 61, at least part of the light-emitting unit 4 is located within the pixel opening 61, an orthographic projection of the pixel opening 61 on the array substrate 5 is located within an orthographic projection of the isolation opening 2 on the array substrate 5.

The first opening 3 may expose part of the side of the pixel defining layer 6 away from the array substrate 5, the first encapsulation layer 10 may be in contact with the side of the pixel defining layer 6 away from the array substrate 5 when the first encapsulation layer 10 fills the first opening 3, a certain adhesion is provided between the first encapsulation layer 10 and the side of the pixel defining layer 6 away from the array substrate 5 that is exposed by the first opening 3, and the stability of the first encapsulation layer 10 can thus be improved.

In one embodiment, the first encapsulation layer 10 completely fills the first opening 3. In this way, the stability of the first encapsulation layer 10 can be improved.

In some embodiments, referring to FIG. 4, grooves 62 are formed on the side of the pixel defining layer 6 away from the array substrate 5, at least part of each groove 62 is exposed within the first opening 3, orthographic projections of the grooves 62 on the array substrate 5 are located within the orthographic projection of the first opening 3 on the array substrate 5, and the first encapsulation layer 10 extends into the grooves 62.

When the pixel openings 61 are formed, grooves 62 may also be formed on the side of the pixel defining layer 6 away from the array substrate 5, and at least one groove 62 may be included at a position corresponding to the same first opening 3. In this way, the material of the first encapsulation layer 10 at the first opening 3 may flow into the grooves 62, the first encapsulation layer 10 eventually filling the first opening 3 may be embedded in the grooves 62, and a concave-convex structure may be formed between the first encapsulation layer 10 filling the first opening 3 and the side of the pixel defining layer 6 away from the array substrate 5, and the adhesion between the first encapsulation layer 10 and the side of the pixel defining layer 6 away from the array substrate 5 can be further increased, and then the stability of the first encapsulation layer 10 can be further enhanced.

In one embodiment, grooves 62 are provided, and the adhesion between the first encapsulation layer 10 and the pixel defining layer 6 can be further increased.

In one embodiment, the orthographic projections of the grooves 62 on the array substrate 5 include a circular or polygonal shape, for example, which may be triangular, quadrilateral, etc.

In some embodiments, referring to FIG. 4 again, a width φ of the orthographic projection of the groove 62 on the array substrate 5 ranges from 2 μm to 10 μm, for example, the width φ can be 2 μm, 3 μm, 5 μm, 7 μm, 9 μm, or 10 μm, etc. The width Y of the groove 62 is rationally set, and the number of the grooves 62 can be rationally set at the first opening 3 on the side of the pixel defining layer 6 away from the array substrate 5, and a greater adhesion between the first encapsulation layer 10 and the pixel defining layer 6 can be achieved.

In one embodiment, referring to FIG. 4 again, a spacing L between orthographic projections of adjacent grooves 62 on the array substrate 5 ranges from 2 μm to 5 μm, for example, the spacing L may be 2 μm, 3 μm, 4 μm, or 5 μm, etc. The spacing L between the grooves 62 is rationally set, and the number of the grooves 62 can be rationally set at the first opening 3 on the side of the pixel defining layer 6 away from the array substrate 5, and a greater adhesion between the first encapsulation layer 10 and the pixel defining layer 6 can be achieved.

In some embodiments, referring to FIG. 3 again, the isolation structure 1 includes a first isolation portion 101 and a second isolation portion 102 sequentially stacked in the direction away from the array substrate 5; an orthographic projection, on the array substrate 5, of a side of the first isolation portion 101 away from the array substrate 5 is within an orthographic projection of the second isolation portion 102 on the array substrate 5; the first embedded structure 12 is in contact with side faces of the first isolation portion 101 and the second isolation portion 102; and the second electrode 9 of the light-emitting unit 4 is electrically connected to the first isolation portion 101. Specifically, the orthographic projection, on the array substrate 5, of the side of the first isolation portion 101 away from the array substrate 5 is within the orthographic projection of the second isolation portion 102 on the array substrate 5.

Since the second isolation portion 102 is located on the side of the first isolation portion 101 away from the array substrate 5, and a transverse width of the second isolation portion 102 is greater than a transverse width of the first isolation portion 101, the second isolation portion 102 disconnects the light-emitting functional layer and the second electrode layer at the isolation structure 1. In this way, the isolation structure 1 formed by the first isolation portion 101 and the second isolation portion 102 can make it easier to encapsulate each light-emitting unit 4 independently.

The first isolation portion 101 includes a conductive material, and the second electrode 9 corresponding to the light-emitting unit 4 extends to come into contact with a side wall of the first isolation portion 101, to electrically connect the second electrode 9 corresponding to the light-emitting unit 4 and a third isolation portion 103.

Since the first isolation portion 101 and the second isolation portion 102 extend laterally with different lengths, an uneven structure may be formed on a side of the first isolation portion 101 and the second isolation portion 102 away from the isolation opening 2, the material of the first encapsulation layer 10 may be embedded with the uneven structure on the side of the first isolation portion 101 and the second isolation portion 102 away from the isolation opening 2, and the first embedded structure 12 is finally formed and the adhesion between the first encapsulation layer 10 and a side of the isolation structure 1 away from the isolation opening 2 can be increased.

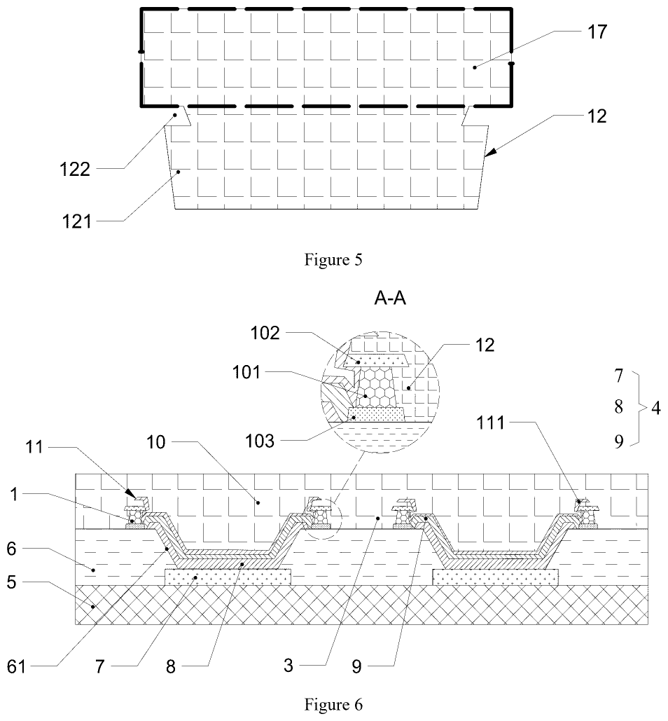

In one embodiment, in some embodiments, referring to FIG. 5, the first embedded structure 12 includes a first embedded portion 121 protruding in a direction close to the isolation structure 1; the first embedded portion 121 is in contact with the first isolation portion 101; and in a direction perpendicular to the array substrate 5, a thickness of the first embedded portion 121 is equal to a height of the first isolation portion 101, and the first embedded portion 121 is formed between the first encapsulation layer 10 filling the first opening 3 and the first isolation portion 101.

The first embedded structure 12 further includes a first recessed portion 122 recessed in a direction away from the isolation structure 1, the first recessed portion 122 being located on a side of the first embedded portion 121 away from the array substrate 5; a side of the first recessed portion 122 close to the array substrate 5 is coplanar with the side of the first embedded portion 121 away from the array substrate 5; and in the direction perpendicular to the array substrate 5, a height of the first recessed portion 122 is equal to a height of the second isolation portion 102, the second isolation portion 102 is embedded in the first recessed portion 122, and the first recessed portion 122 is formed between the first encapsulation layer 10 filling the first opening 3 and the second isolation portion 102.

In this way, the first encapsulation layer 10 filling the first opening 3 extends from the side face of the first isolation portion 101 to a side of the second isolation portion 102 close to the array substrate 5 and then extends from the side face of the second isolation portion 102 to a side of the second isolation portion 102 away from the array substrate 5, and the adhesion between the first encapsulation layer 10 and the side of the isolation structure 1 away from the isolation opening 2 can be increased.

In one embodiment, a cross-section of the first isolation portion 101 in a thickness direction of the array substrate 5 is a regular trapezoid. In this way, it is possible to make it easier to form the first embedded structure between the first encapsulation layer 10 and the isolation structure 1.

In one embodiment, the orthographic projection of the first isolation portion 101 on the array substrate 5 is located within the orthographic projection of the second isolation portion 102 on the array substrate 5. In this way, the light-emitting functional layer and the second electrode layer are more easily disconnected at the isolation structure 1.

In one embodiment, an orthographic projection of the first recessed portion 122 on the array substrate 5 has the same shape as an orthographic projection of the first embedded portion 121 on the array substrate 5, the orthographic projection of the first recessed portion 122 on the array substrate 5 has the same shape as the orthographic projection of the first opening 3 on the array substrate 5, a geometric center of the orthographic projection of the first recessed portion 122 on the array substrate 5 coincides with a geometric center of the orthographic projection of the first embedded portion 121 on the array substrate 5, the geometric center of the orthographic projection of the first recessed portion 122 on the array substrate 5 coincides with a geometric center of the orthographic projection of the first opening 3 on the array substrate 5, and the orthographic projection of the first recessed portion 122 on the array substrate 5 is within the orthographic projection of the first embedded portion 121 on the array substrate 5. In this way, the structure of the first embedded structure 12 at a circumferential side is substantially the same, it is possible to improve the uniformity of the connection of the first embedded structure 12 to the isolation structure 1 at different positions, and ultimately to further improve the adhesion between the first encapsulation layer 10 and the isolation structure 1.

In some embodiments, referring to FIG. 6, the isolation structure 1 includes a third isolation portion 103, a first isolation portion 101 and a second isolation portion 102 which are sequentially stacked in the direction away from the array substrate 5; an orthographic projection, on the array substrate 5, of a side of the first isolation portion 101 away from the array substrate 5 is within an orthographic projection of the second isolation portion 102 on the array substrate 5, and an orthographic projection of the first isolation portion 101 on the array substrate 5 is within an orthographic projection of the third isolation portion 103 on the array substrate 5; and the first embedded structure 12 is in contact with a side face of each of the third isolation portion 103, the first isolation portion 101 and the second isolation portion 102. The second electrode 9 of the light-emitting unit 4 is electrically connected to the third isolation portion 103, and a material of the third isolation portion 103 includes a molybdenum metal; or a material of the first isolation portion 101 includes an aluminum metal; or a material of the second isolation portion 102 includes a titanium metal.

Since the orthographic projection of the first isolation portion 101 on the array substrate 5 is within the orthographic projection of the third isolation portion 103 on the array substrate 5, part of the third isolation portion 103 is exposed relative to the first isolation portion 101, and an uneven structure may be formed on a side of the third isolation portion 103, the first isolation portion 101 and the second isolation portion 102 that is away from the isolation opening 2; and the material of the first encapsulation layer 10 may be embedded with the uneven structure on the side of the third isolation portion 103, the first isolation portion 101 and the second isolation portion 102 that is away from the isolation opening 2, and the first embedded structure 12 is finally formed and the adhesion between the first encapsulation layer 10 and a side of the isolation structure 1 away from the isolation opening 2 can be increased.

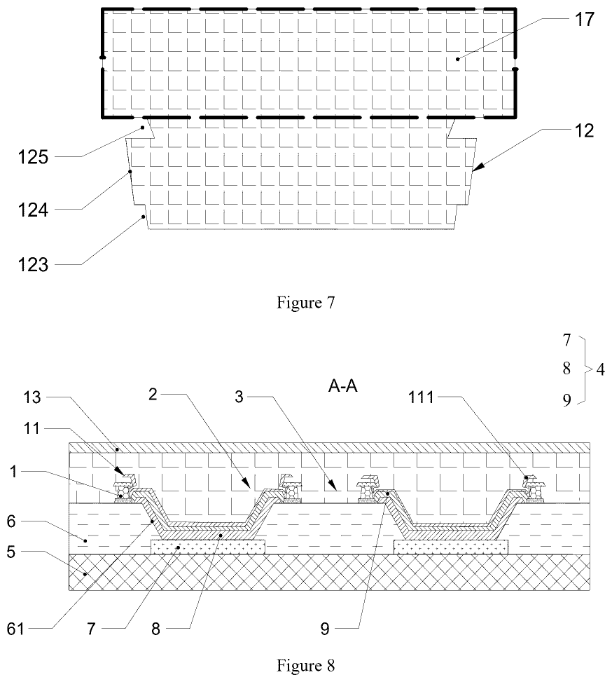

In one embodiment, referring to FIG. 7, in some other embodiments, the first embedded structure 12 includes a second recessed portion 123 recessed in a direction away from the isolation structure 1; in the direction perpendicular to the array substrate 5, a height of the second recessed portion 123 is equal to a height of the third isolation portion 103; the third isolation portion 103 is embedded in the second recessed portion 123; and the second recessed portion 123 is formed between the first encapsulation layer 10 filling the first opening 3 and the third isolation portion 103.

The first embedded structure 12 further includes a second embedded portion 124 protruding in a direction close to the isolation structure 1, the second embedded portion 124 being in contact with the first isolation portion 101; in the direction perpendicular to the array substrate 5, a thickness of the second embedded portion 124 is equal to the height of the first isolation portion 101; the second embedded portion 124 is located on a side of the second recessed portion 123 away from the array substrate 5; a side of the second embedded portion 124 close to the array substrate 5 is coplanar with the side of the second recessed portion 123 away from the array substrate 5; and the second embedded portion 124 is formed between the first encapsulation layer 10 filling the first opening 3 and the first isolation portion 101.

The first embedded structure 12 includes a third recessed portion 125 recessed in a direction away from the isolation opening 2; in the direction perpendicular to the array substrate 5, a height of the third recessed portion 125 is equal to the height of the second isolation portion 102; the second isolation portion 102 is embedded in the third recessed portion 125; the third recessed portion 125 is located on a side of the second embedded portion 124 away from the array substrate 5; a side of the third recessed portion 125 close to the array substrate 5 is coplanar with the side of the second embedded portion 124 away from the array substrate 5; and the third recessed portion 125 is formed between the first encapsulation layer 10 filling the first opening 3 and the second isolation portion 102.

In this way, the first encapsulation layer 10 filling the first opening 3 extends from a side face of the third isolation portion 103 to a side of the third isolation portion 103 away from the array substrate 5, then extends from the side face of the first isolation portion 101 to the side of the second isolation portion 102 close to the array substrate 5, and finally extends from the side face of the second isolation portion 102 to the side of the second isolation portion 102 away from the array substrate 5, and the adhesion between the first encapsulation layer 10 and the side of the isolation structure 1 away from the isolation opening 2 can be increased.

In one embodiment, an orthographic projection of the third isolation portion on the array substrate is within an orthographic projection of the second isolation portion on the array substrate, an orthographic projection of the third recessed portion on the array substrate is within an orthographic projection of the second recessed portion on the array substrate, the orthographic projection of the third recessed portion on the array substrate is within an orthographic projection of the second embedded portion on the array substrate, and the orthographic projection of the second recessed portion on the array substrate is within the orthographic projection of the second embedded portion on the array substrate; the orthographic projection of the second recessed portion on the array substrate has the same shape as the orthographic projection of the third recessed portion on the array substrate, the orthographic projection of the second recessed portion on the array substrate has the same shape as the orthographic projection of the second embedded portion on the array substrate, and the orthographic projection of the second recessed portion on the array substrate has the same shape as an orthographic projection of the first opening on the array substrate; and a geometric center of the orthographic projection of the second recessed portion on the array substrate coincides with a geometric center of the orthographic projection of the third recessed portion on the array substrate, the geometric center of the orthographic projection of the second recessed portion on the array substrate coincides with a geometric center of the orthographic projection of the second embedded portion on the array substrate, and the geometric center of the orthographic projection of the second recessed portion on the array substrate coincides with a geometric center of the orthographic projection of the first opening on the array substrate.

In this way, the structure of the first embedded structure 12 at a circumferential side is substantially the same, it is possible to improve the uniformity of the connection of the first embedded structure 12 to the isolation structure 1 at different positions, and ultimately to further improve the adhesion between the first encapsulation layer 10 and the isolation structure 1.

In some embodiments, referring to FIG. 8, the display panel further includes a third encapsulation layer 13 on a side of the first encapsulation layer 10 away from the array substrate 5, materials of the second encapsulation layer 11 and the third encapsulation layer 13 each including an inorganic material, and the material of the first encapsulation layer 10 including an organic material.

The second encapsulation layer 11, the first encapsulation layer 10 and the third encapsulation layer 13 form an encapsulation layer of the display panel, which can be better encapsulated by the encapsulation layer.

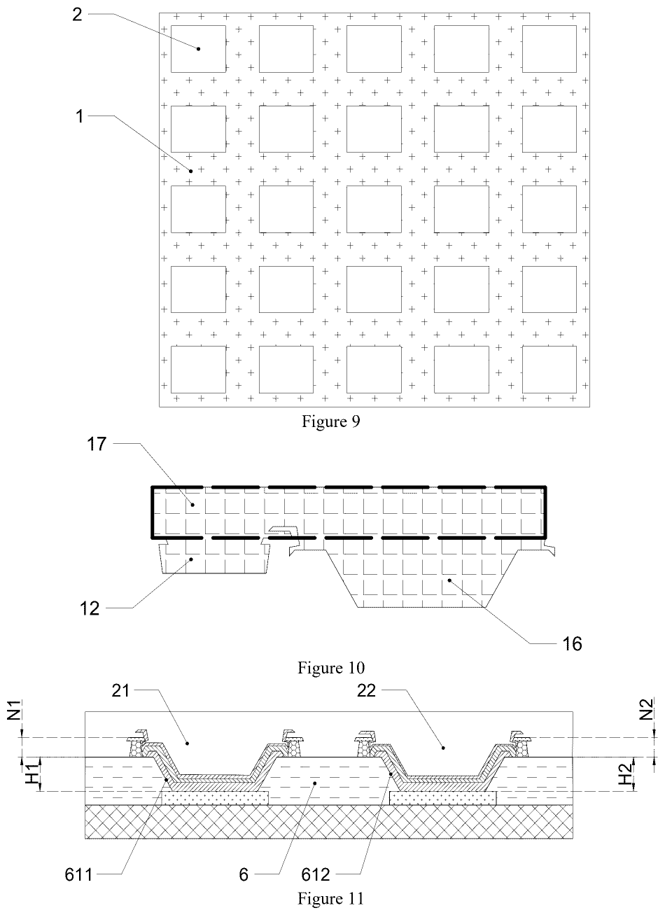

In one embodiment, referring to FIG. 9, an orthographic projection of the isolation structure 1 on the array substrate 5 is a mesh structure. In this way, it is easier to independently encapsulate the light-emitting unit 4.

In some embodiments, referring to FIG. 10, the first encapsulation layer 10 further includes a second embedded structure 16, where the second embedded structure 16 is located within the isolation opening 2, the second embedded structure 16 is in contact with a side of the encapsulation unit 111 away from the array substrate 5, a distance from a side of the first embedded structure 12 away from the array substrate 5 to the array substrate 5 is equal to a distance from a side of the second embedded structure 16 away from the array substrate 5 to the array substrate 5, and in the direction away from the array substrate 5, a thickness of the first embedded structure 12 is less than a thickness of the second embedded structure 16. The first encapsulation layer 10 further includes a base 17 on the side of the first embedded structure 12 and the second embedded structure 16 away from the array substrate 5, the base 17 being integrally formed with the first embedded structure 12 and the second embedded structure 16.

The second embedded structure 16 is embedded in the isolation opening 2, and the adhesion between the first encapsulation layer 10 and the isolation structure 1 and the encapsulation unit 111 can be further improved, and then the stability of the first encapsulation layer 10 can be further enhanced.

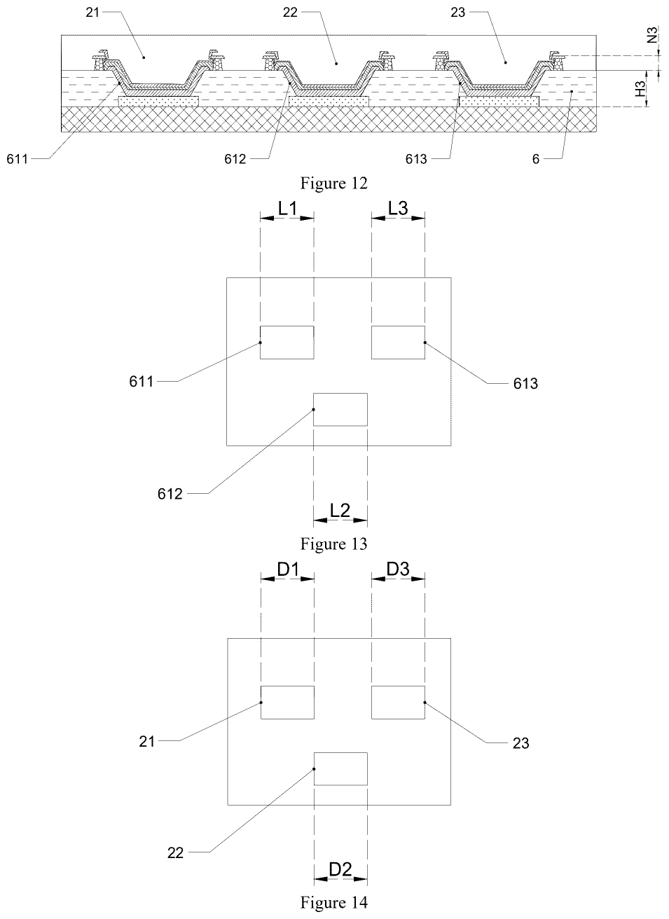

In some embodiments, referring to FIGS. 11-14, the pixel openings 61 include a first pixel opening 611, a second pixel opening 612 and a third pixel opening 613, and the isolation openings 2 include a first isolation opening 21, a second isolation opening 22 and a third isolation opening 23.

In some embodiments, a depth H1 of the first pixel opening 611, a depth H2 of the second pixel opening 612, and a depth H3 of the third pixel opening 613 are equal in the direction perpendicular to the array substrate 5.

In an arrangement direction of the pixel openings 61, a size L1 of an orthographic projection of the first pixel opening 611 on the array substrate 5, a size L2 of an orthographic projection of the second pixel opening 612 on the array substrate 5, and a size L3 of an orthographic projection of the third pixel opening 613 on the array substrate 5 are equal.

In the direction perpendicular to the array substrate 5, a depth N1 of the first isolation opening 21, a depth N2 of the second isolation opening 22, and a depth N3 of the third isolation opening 23 are equal.

In an arrangement direction of the isolation openings 2, a size D1 of an orthographic projection of the first isolation opening 21 on the array substrate 5, a size D2 of an orthographic projection of the second isolation opening 22 on the array substrate 5, and a size D3 of an orthographic projection of the third isolation opening 23 on the array substrate 5 are equal.

In this way, the second embedded structures 16 corresponding to different light-emitting units in this embodiment have the same shape and size.

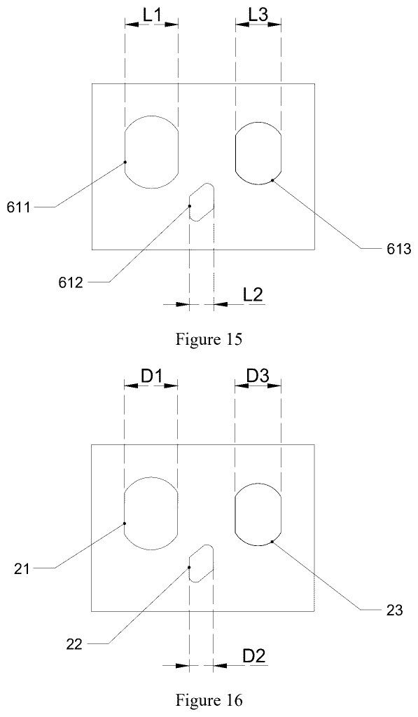

In some other embodiments, referring to FIGS. 11-12 and 15-16, in the direction perpendicular to the array substrate 5, the depth of the first pixel opening 611 is not equal to the depth of at least one of the second pixel opening 612 and the third pixel opening 613, i.e., the depth H1 of the first pixel opening 611 is not equal to the depth H2 of the second pixel opening 612 or the depth H3 of the third pixel opening 613.

In an arrangement direction of the pixel openings 61, the size of the orthographic projection of the first pixel opening 611 on the array substrate 5 is not equal to the size of the orthographic projection of at least one of the second pixel opening 612 and the third pixel opening 613 on the array substrate 5, i.e., the size L1 of the orthographic projection of the first pixel opening 611 on the array substrate 5 is not equal to the size L2 of the orthographic projection of the second pixel opening 612 on the array substrate 5 or the size L3 of the orthographic projection of the third pixel opening 613 on the array substrate 5.

In the direction perpendicular to the array substrate 5, the depth of the first isolation opening 21 is not equal to the depth of at least one of the second isolation opening 22 and the third isolation opening 23, i.e., the depth N1 of the first isolation opening 21 is not equal to the depth N2 of the second isolation opening 22 or the depth N3 of the third isolation opening 23.

In an arrangement direction of the isolation openings 2, the size of the orthographic projection of the first isolation opening 21 on the array substrate 5 is not equal to the size of the orthographic projection of at least one of the second isolation opening 22 and the third isolation opening 23 on the array substrate 5, i.e., the size D1 of the orthographic projection of the first isolation opening 21 on the array substrate 5 is not equal to the size D2 of the orthographic projection of the second isolation opening 22 on the array substrate 5 or the size D3 of the orthographic projection of the third isolation opening 23 on the array substrate 5.

In this way, the second embedded structures 16 corresponding to the different light-emitting units in this embodiment have different shapes and sizes.

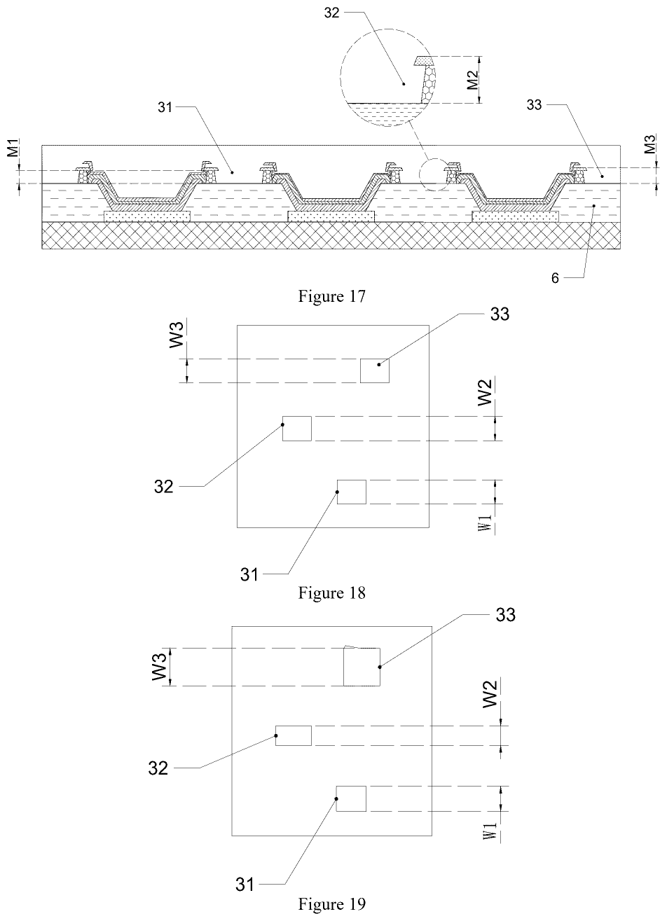

In some embodiments, referring to FIGS. 17 and 18, the first openings 3 include light-transmitting openings including a first light-transmitting opening 31, a second light-transmitting opening 32 and a third light-transmitting opening 33.

In some embodiments, a depth M1 of the first light-transmitting opening 31, a depth M2 of the second light-transmitting opening 32, and a depth M3 of the third light-transmitting opening 33 are equal in the direction perpendicular to the array substrate 5.

In an arrangement direction of the light-transmitting openings, a size W1 of an orthographic projection of the first light-transmitting opening 31 on the array substrate 5, a size W2 of an orthographic projection of the second light-transmitting opening 32 on the array substrate 5, and a size W3 of an orthographic projection of the third light-transmitting opening 33 on the array substrate 5 are equal.

In this way, the first embedded structures 12 corresponding to the different light-emitting units in this embodiment have the same shape and size.

In some other embodiments, referring to FIGS. 17 and 19, in the direction perpendicular to the array substrate 5, the depth of the first light-transmitting opening 31 is not equal to the depth of at least one of the second light-transmitting opening 32 and the third light-transmitting opening 33, i.e., the depth M1 of the first light-transmitting opening 31 is not equal to the depth M2 of the second light-transmitting opening 32 or the depth M3 of the third light-transmitting opening 33.

In the arrangement direction of the light-transmitting openings, the size of the orthographic projection of the first light-transmitting opening 31 on the array substrate 5 is not equal to the size of the orthographic projection of at least one of the second light-transmitting opening 32 and the third light-transmitting opening 33 on the array substrate 5, i.e., the size W1 of the orthographic projection of the first light-transmitting opening 31 on the array substrate 5 is not equal to the size W2 of the orthographic projection of the second light-transmitting opening 32 on the array substrate 5 or the size W3 of the orthographic projection of the third light-transmitting opening 33 on the array substrate 5.

In this way, the first embedded structures 12 corresponding to the different light-emitting units in this embodiment have different shapes and sizes.

In summary, in the present application, the first encapsulation layer 10 is configured to include the first embedded structure 12, and the first embedded structure 12 is located in the first opening 3 and is in contact with the isolation structure 1, which can increase the adhesion between the first encapsulation layer 10 and the isolation structure 1 and thus the stability of the first encapsulation layer 10, and in turn can improve the quality of the display panel.

In some embodiments, referring to FIGS. 1-3 again, the present application also provides a further display panel, the display panel including a first active area AB and a second active area AA at least partially surrounding the first active area AB, and the display panel including an array substrate 5, an isolation structure 1 and a first encapsulation layer 10.

The isolation structure 1 is located on one side of the array substrate 5, and at least part of the isolation structure 1 encloses first openings 3, each of the first openings 3 being located in the first active area AB.

A photosensitive device is provided at a position corresponding to the first active area AB, for example, a camera may be provided, at which light reaches through the first opening 3, to achieve a camera function of the display panel.

The first encapsulation layer 10 at least partially fills the first opening 3 and is in contact with the side of the at least part of the isolation structure 1 close to the first opening 3, and a first embedded structure 12 is formed between the first encapsulation layer 10 and the side of the isolation structure 1 close to the first opening 3.

The first encapsulation layer 10 may be formed by means of ink-jet printing, a material of the first encapsulation layer 10 may flow into the first opening 3 to completely fill the first opening 3, and the material of the first encapsulation layer 10 has a high light transmittance, and light can pass through the first opening 3 more easily to the position of the corresponding photosensitive device, thus the display panel can have a better transmittance.

The first encapsulation layer 10 may extend into contact with the side of the isolation structure 1 close to the first opening 3 and forms the first embedded structure 12 with the side of the isolation structure 1 close to the first opening 3, and the first embedded structure 12 may increase the adhesion between the first encapsulation layer 10 and the isolation structure 1, and it is possible to enhance the stability of the first encapsulation layer 10, and the first encapsulation layer 10 is not likely to suffer from problems such as delamination, which may ultimately improve the quality of the display panel.

In some embodiments, referring to FIG. 4 again, the present application further provides yet a further display panel, including an array substrate 5, a pixel defining layer 6, an isolation structure 1 and a first encapsulation layer 10.

The pixel defining layer 6 is located on one side of the array substrate 5, and grooves 62 are formed on a side of the pixel defining layer 6 away from the array substrate 5.

The isolation structure 1 is located on the side of the pixel defining layer 6 away from the array substrate 5, at least part of the isolation structure 1 encloses first openings 3, and at least part of the groove 62 is exposed in each of the first openings 3.

The display panel further includes a light-emitting unit 4 at least partially located within the isolation opening 2 and a second encapsulation layer 11 located on a side of the light-emitting unit 4 away from the array substrate 5, where the second encapsulation layer 11 includes encapsulation units 111, at least part of the encapsulation unit 111 extends from a side face of the isolation structure 1 to a side of the isolation structure 1 away from the array substrate 5, and the side face of the isolation structure 1 is a face of the isolation structure 1 facing the isolation opening 2.

The first encapsulation layer 10 is located on a side of the second encapsulation layer 11 away from the array substrate 5, and the first encapsulation layer 10 at least partially fills the first opening 3 and extends into the grooves 62.

When the pixel openings 61 are formed, grooves 62 may also be formed on the side of the pixel defining layer 6 away from the array substrate 5, and at least one groove 62 may be included at a position corresponding to the same first opening 3. In this way, the material of the first encapsulation layer 10 at the first opening 3 may flow into the grooves 62, the first encapsulation layer 10 eventually filling the first opening 3 may be embedded in the grooves 62, and a concave-convex structure may be formed between the first encapsulation layer 10 filling the first opening 3 and the side of the pixel defining layer 6 away from the array substrate 5, and the adhesion between the first encapsulation layer 10 and the side of the pixel defining layer 6 away from the array substrate 5 can be further increased, and then the stability of the first encapsulation layer 10 can be further enhanced.

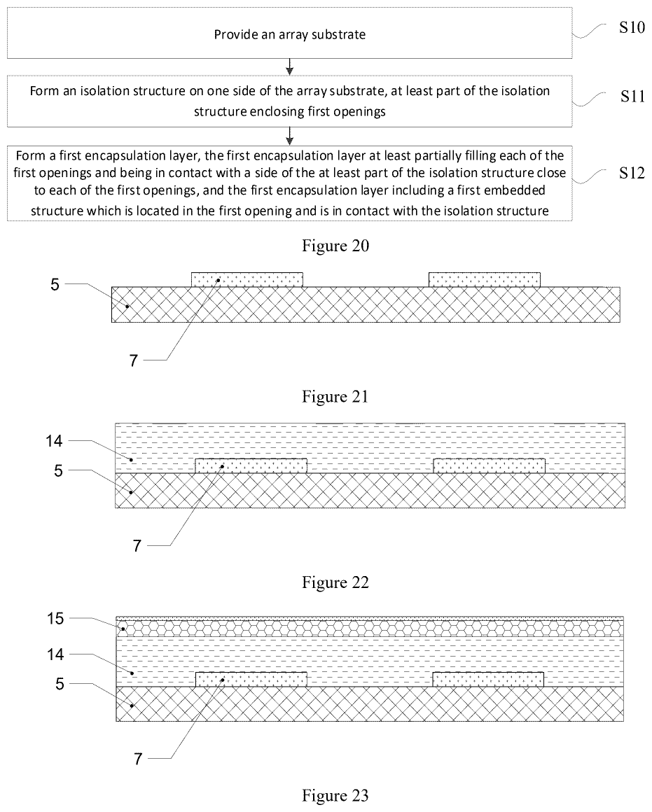

In some embodiments, referring to FIG. 20, the present application further provides a method for preparing a display panel, the display panel including a first active area AB and a second active area AA at least partially surrounding the first active area AB, and the method is implemented as follows:

In step S10, an array substrate 5 is provided.

The array substrate 5 may include a substrate and drive units located on one side of the substrate, and each drive unit may include one or more semiconductor switching devices. The semiconductor switching device may be formed collectively by film layers in the array substrate 5. For example, the semiconductor switching device may be a thin film transistor formed collectively by the plurality of film layers.

In step S11, an isolation structure 1 is formed on one side of the array substrate 5, at least part of the isolation structure 1 enclosing isolation openings 2 and first openings 3, and each of the first openings 3 being located in the first active area AB.

Referring to FIG. 21, a first electrode layer is formed on one side of the array substrate 5, the first electrode layer including first electrodes 7 arranged at intervals.

Referring to FIG. 22, a pixel defining material layer 14 is formed on a side of the first electrode 7 away from the array substrate 5.

Referring to FIG. 23, an isolation structure material layer 15 is formed on a side of the pixel defining material layer 14 away from the array substrate 5.

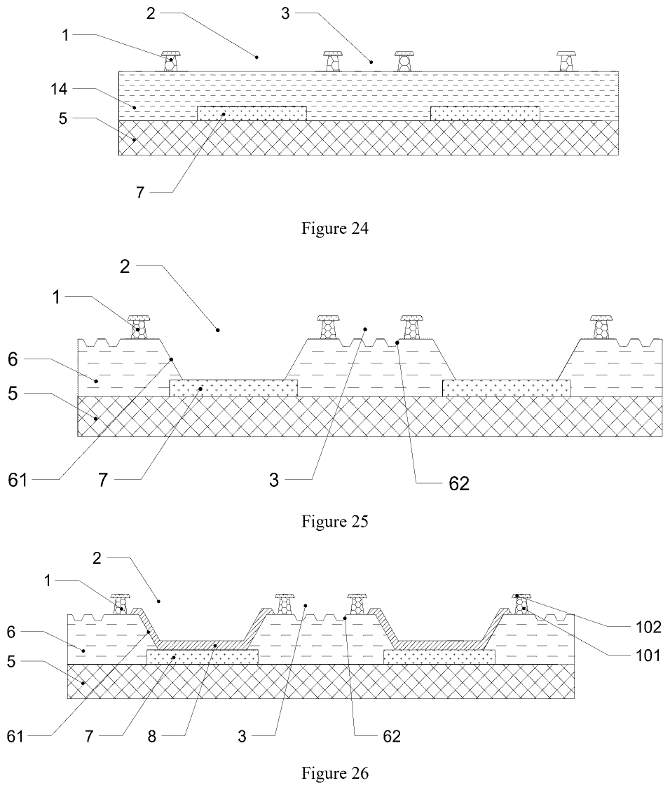

Referring to FIG. 24, the isolation structure material layer 15 is patterned to form an isolation structure 1.

Referring to FIG. 25, pixel openings 61 and grooves 62 are formed on the pixel defining material layer 14 by means of a halftone mask to form a pixel defining layer 6. In this way, the pixel defining layer 6 may be formed on the side of the first electrode 7 away from the array substrate 5, and the isolation structure 1 may be formed on a side of the pixel defining layer 6 away from the array substrate 5.

With the halftone mask, while the pixel openings 61 are formed in the second active area AA, the grooves 62 may be formed in the first active area AB, and a specific process for forming the grooves 62 is not required, thereby reducing the cost of preparing the display panel.

A light-emitting unit 4 is prepared, and at least part of the light-emitting unit 4 is located in each of the isolation openings 2.

Referring to FIG. 26, a light-emitting functional layer is formed in the isolation opening 2, the light-emitting functional layer is broken at the isolation structure 1, and finally a light-emitting portion 8 is formed in the isolation opening 2.

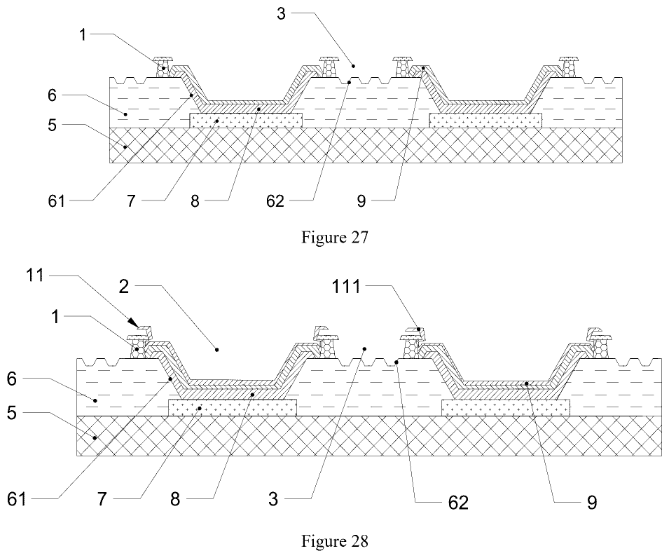

Referring to FIG. 27, the isolation opening 2 is formed with a second electrode layer on a side of the light-emitting functional layer away from the array substrate 5, the second electrode layer being broken at the isolation structure 1, and finally a second electrode 9 is formed in the isolation opening 2, the second electrode 9 extending to electrically connect with the isolation structure 1.

In step S12, a first encapsulation layer 10 is formed, the first encapsulation layer 10 at least partially fills the first opening 3 and is in contact with a side of the at least part of the isolation structure 1 close to the first opening 3, the first encapsulation layer 10 includes a first embedded structure 12, and the first embedded structure 12 is located in the first opening 3 and is in contact with the isolation structure 1.

Referring to FIG. 28, a second encapsulation layer 11 is formed on a side of the second electrode layer away from the array substrate 5, in the process of patterning the light-emitting units 4, the second encapsulation layer 11 is disconnected at the isolation structure 1 to form encapsulation units 111, and the encapsulation units 111 can encapsulate the corresponding light-emitting units 4 completely separately, and the display characteristics of the display panel can be improved.

Referring to FIG. 4 again, a first encapsulation layer 10 is formed on a side of the second encapsulation layer 11 away from the array substrate 5, the first encapsulation layer 10 may extend into the isolation opening 2, the first encapsulation layer 10 extending into the isolation opening 2 forms a first embedded structure 12, the first embedded structure 12 is in contact with the isolation structure 1, and the first embedded structure 12 may increase the adhesion between the first encapsulation layer 10 and the isolation structure 1.

In this way, the material of the first encapsulation layer 10 at the first opening 3 may flow into the grooves 62, the first encapsulation layer 10 eventually filling the first opening 3 may be embedded in the grooves 62, a concave-convex structure may be formed between the first encapsulation layer 10 filling the first opening 3 and the side of the pixel defining layer 6 away from the array substrate 5, and the concave-convex structure may increase the adhesion between the first encapsulation layer 10 and the pixel defining layer. The stability of the first encapsulation layer 10 can finally be enhanced, and the first encapsulation layer 10 is not likely to suffer from problems such as delamination, thus the quality of the display panel formed by this method can be improved.

In some embodiments, the present application further provides an electronic device, including a display panel in the present application, or including a display panel prepared by means of a method for preparing the display panel in the present application. The electronic device may include a device having image processing capability, for example, a server, a personal computer, a notebook computer, etc. Since the electronic device includes the display panel in the present application, the electronic device is of higher quality.

The embodiments may be combined in any manner. For the purpose of simplicity in description, not all possible combinations of the above-described embodiments are described. However, as long as the combinations of these features do not conflict with each other, the combinations shall all fall within the scope of the description.

The above embodiments merely represent several implementations of the present application, giving specifics and details thereof, but should not be understood as limiting the scope of the present application thereby. It should be noted that various variations and improvements may also be made without departing from the spirit of the present application and shall fall within the scope of protection of the present application. Therefore, the scope of protection of the present application shall be in accordance with the appended claims.

1. A display panel, comprising:
an array substrate;
an isolation structure located on one side of the array substrate, at least part of the isolation structure enclosing first openings; and
a first encapsulation layer at least partially filling each of the first openings and being in contact with a side of the at least part of the isolation structure close to each of the first openings, the first encapsulation layer comprising a first embedded structure, and the first embedded structure being located in the first opening and being in contact with the isolation structure.

2. The display panel according to claim 1, wherein the isolation structure comprises a first isolation portion and a second isolation portion sequentially stacked in a direction away from the array substrate, the first embedded structure being in contact with side faces of the first isolation portion and the second isolation portion, wherein a cross-section of the first isolation portion in a thickness direction of the array substrate is a regular trapezoid;
an orthographic projection of the first isolation portion on the array substrate is within an orthographic projection of the second isolation portion on the array substrate;
an orthographic projection, on the array substrate, of a side of the first isolation portion away from the array substrate is within the orthographic projection of the second isolation portion on the array substrate,
wherein the first embedded structure comprises a first embedded portion protruding in a direction close to the isolation structure;
the first embedded portion is in contact with the first isolation portion; and
in a direction perpendicular to the array substrate, a thickness of the first embedded portion is equal to a height of the first isolation portion.

3. The display panel according to claim 2, wherein the first embedded structure further comprises a first recessed portion recessed in a direction away from the isolation structure;
the second isolation portion is embedded in the first recessed portion;
the first recessed portion is located on a side of the first embedded portion away from the array substrate;
a side of the first recessed portion close to the array substrate is coplanar with the side of the first embedded portion away from the array substrate; and in the direction perpendicular to the array substrate, a height of the first recessed portion is equal to a height of the second isolation portion, wherein an orthographic projection of the first recessed portion on the array substrate has the same shape as an orthographic projection of the first embedded portion on the array substrate;
the orthographic projection of the first recessed portion on the array substrate has the same shape as an orthographic projection of the first opening on the array substrate; a geometric center of the orthographic projection of the first recessed portion on the array substrate coincides with a geometric center of the orthographic projection of the first embedded portion on the array substrate;
the geometric center of the orthographic projection of the first recessed portion on the array substrate coincides with a geometric center of the orthographic projection of the first opening on the array substrate; and
the orthographic projection of the first recessed portion on the array substrate is within the orthographic projection of the first embedded portion on the array substrate.

4. The display panel according to claim 1, wherein the isolation structure comprises a third isolation portion, a first isolation portion and a second isolation portion which are sequentially stacked in a direction away from the array substrate, an orthographic projection, on the array substrate, of a side of the first isolation portion away from the array substrate being within an orthographic projection of the second isolation portion on the array substrate, an orthographic projection of the first isolation portion on the array substrate being within an orthographic projection of the third isolation portion on the array substrate, and the first embedded structure being in contact with a side face of each of the first isolation portion, the second isolation portion and the third isolation portion, wherein the first embedded structure comprises a second recessed portion recessed in a direction away from the isolation structure;
in a direction perpendicular to the array substrate, a height of the second recessed portion is equal to a height of the third isolation portion;
the third isolation portion is embedded in the second recessed portion;
the first embedded structure further comprises a second embedded portion protruding in a direction close to the isolation structure;
the second embedded portion is in contact with the first isolation portion;
in the direction perpendicular to the array substrate, a thickness of the second embedded portion is equal to a height of the first isolation portion;
the second embedded portion is located on a side of the second recessed portion away from the array substrate; and
a side of the second embedded portion close to the array substrate is coplanar with the side of the second recessed portion away from the array substrate.

5. The display panel according to claim 4, wherein at least part of the isolation structure encloses isolation openings, and the first embedded structure comprises a third recessed portion recessed in a direction away from each of the isolation openings;
in the direction perpendicular to the array substrate, a height of the third recessed portion is equal to a height of the second isolation portion;
the second isolation portion is embedded in the third recessed portion;
the third recessed portion is located on a side of the second embedded portion away from the array substrate; and
a side of the third recessed portion close to the array substrate is coplanar with the side of the second embedded portion away from the array substrate.

6. The display panel according to claim 5, wherein a cross-section of the first isolation portion in a thickness direction of the array substrate is a regular trapezoid;
an orthographic projection of the first isolation portion on the array substrate is within an orthographic projection of the second isolation portion on the array substrate;
an orthographic projection of the third isolation portion on the array substrate is within the orthographic projection of the second isolation portion on the array substrate;
an orthographic projection of the third recessed portion on the array substrate is within an orthographic projection of the second recessed portion on the array substrate;
the orthographic projection of the third recessed portion on the array substrate is within an orthographic projection of the second embedded portion on the array substrate;
the orthographic projection of the second recessed portion on the array substrate is within the orthographic projection of the second embedded portion on the array substrate; and
the orthographic projection of the second recessed portion on the array substrate has the same shape as the orthographic projection of the third recessed portion on the array substrate.

7. The display panel according to claim 5, wherein an orthographic projection of the second recessed portion on the array substrate has the same shape as an orthographic projection of the second embedded portion on the array substrate;
the orthographic projection of the second recessed portion on the array substrate has the same shape as an orthographic projection of the first opening on the array substrate;
a geometric center of the orthographic projection of the second recessed portion on the array substrate coincides with a geometric center of an orthographic projection of the third recessed portion on the array substrate;
the geometric center of the orthographic projection of the second recessed portion on the array substrate coincides with a geometric center of the orthographic projection of the second embedded portion on the array substrate; and
the geometric center of the orthographic projection of the second recessed portion on the array substrate coincides with a geometric center of the orthographic projection of the first opening on the array substrate.

8. The display panel according to claim 1, wherein at least part of the isolation structure encloses isolation openings, and the display panel further comprises a light-emitting unit located at least partially within each of the isolation openings;
an orthographic projection of the isolation opening on the array substrate is outside an orthographic projection of the first opening on the array substrate;
the isolation opening is spaced apart from the first opening; and
the light-emitting unit comprises a first electrode, a light-emitting portion and a second electrode located at least partially in the isolation opening and sequentially stacked in a direction away from the array substrate, the second electrode being electrically connected to the isolation structure.

9. The display panel according to claim 8, wherein the display panel further comprises a second encapsulation layer on a side of the light-emitting unit away from the array substrate, the second encapsulation layer comprising a plurality of encapsulation units, and at least part of the plurality of encapsulation units is located within the isolation opening and extends from a side face of the isolation structure to a side of the isolation structure away from the array substrate;
the display panel further comprises a third encapsulation layer located on a side of the first encapsulation layer away from the array substrate;
a material of the third encapsulation layer comprises an inorganic material; and
a material of the first encapsulation layer comprises an organic material.

10. The display panel according to claim 8, wherein the first encapsulation layer further comprises a second embedded structure located in the isolation opening;
the second embedded structure is in contact with a side of the at least part of the plurality of encapsulation units away from the array substrate;
a distance from a side of the first embedded structure away from the array substrate to the array substrate is equal to a distance from a side of the second embedded structure away from the array substrate to the array substrate; and
in the direction away from the array substrate, a thickness of the first embedded structure is less than a thickness of the second embedded structure, wherein the first encapsulation layer further comprises a base on a side of the first embedded structure and the second embedded structure away from the array substrate, the base being integrally formed with the first embedded structure and the second embedded structure.

11. The display panel according to claim 9, wherein at least part of the first encapsulation layer is located on a side of the second encapsulation layer away from the array substrate;
a material of the second encapsulation layer comprises an inorganic material;
adjacent encapsulation units are spaced apart on the side of the isolation structure away from the array substrate;
a gap is provided between the encapsulation unit located on the side of the isolation structure away from the array substrate and the side of the isolation structure away from the array substrate; and
the first encapsulation layer fills the gap.

12. The display panel according to claim 1, wherein the display panel further comprises a pixel defining layer on one side of the array substrate, the isolation structure is located on a side of the pixel defining layer away from the array substrate, and the first encapsulation layer filling the first opening is in contact with the side of the pixel defining layer away from the array substrate;
the pixel defining layer comprises a plurality of pixel openings; and
at least part of the isolation structure encloses isolation openings, and an orthographic projection of the pixel opening on the array substrate is within an orthographic projection of each of the isolation openings on the array substrate.

13. The display panel according to claim 12, wherein the pixel openings comprise a first pixel opening and a second pixel opening, and a depth of the first pixel opening and a depth of the second pixel opening are equal in a direction perpendicular to the array substrate;
in an arrangement direction of the pixel openings, a size of an orthographic projection of the first pixel opening on the array substrate and a size of an orthographic projection of the second pixel opening on the array substrate are equal;
the pixel openings further comprise a third pixel opening, and a depth of the third pixel opening is equal to both of the depth of the first pixel opening and the depth of the second pixel opening in the direction perpendicular to the array substrate;
in the arrangement direction of the pixel openings, the size of the orthographic projection of the first pixel opening on the array substrate is equal to the size of the orthographic projection of the second pixel opening on the array substrate and a size of an orthographic projection of the third pixel opening on the array substrate;
the isolation openings comprise a first isolation opening and a second isolation opening, and depths of the first isolation opening and the second isolation opening are equal in the direction perpendicular to the array substrate;
in an arrangement direction of the isolation openings, a size of an orthographic projection of the first isolation opening on the array substrate is equal to a size of an orthographic projection of the second isolation opening on the array substrate;
the isolation openings further comprise a third isolation opening, and a depth of the third isolation opening is equal to each of the depths of the first isolation opening and the second isolation opening in the direction perpendicular to the array substrate; and
in the arrangement direction of the isolation openings, the size of the orthographic projection of the first isolation opening on the array substrate is equal to the size of the orthographic projection of the second isolation opening on the array substrate and a size of an orthographic projection of the third isolation opening on the array substrate.

14. The display panel according to claim 1, wherein the first openings comprise light-transmitting openings comprising a first light-transmitting opening and a second light-transmitting opening, and depths of the first light-transmitting opening and the second light-transmitting opening are equal in a direction perpendicular to the array substrate;
in an arrangement direction of the light-transmitting openings, a size of an orthographic projection of the first light-transmitting opening on the array substrate is equal to a size of an orthographic projection of the second light-transmitting opening on the array substrate;
the light-transmitting openings further comprise a third light-transmitting opening, and a depth of the third light-transmitting opening is equal to each of the depths of the first light-transmitting opening and the second light-transmitting opening in the direction perpendicular to the array substrate; and
in the arrangement direction of the light-transmitting openings, the size of the orthographic projection of the first light-transmitting opening on the array substrate is equal to the size of the orthographic projection of the second light-transmitting opening on the array substrate and a size of an orthographic projection of the third light-transmitting opening on the array substrate.

15. The display panel according to claim 12, wherein the pixel openings comprise a first pixel opening and a second pixel opening, and a depth of the first pixel opening and a depth of the second pixel opening are not equal in a direction perpendicular to the array substrate;
in an arrangement direction of the pixel openings, a size of an orthographic projection of the first pixel opening on the array substrate and a size of an orthographic projection of the second pixel opening on the array substrate are not equal;
the pixel openings further comprise a third pixel opening, and a depth of the third pixel opening is not equal to the depth of at least one of the first pixel opening and the second pixel opening in the direction perpendicular to the array substrate;
in the arrangement direction of the pixel openings, the size of the orthographic projection of the first pixel opening on the array substrate is not equal to at least one of the size of the orthographic projection of the second pixel opening on the array substrate and a size of an orthographic projection of the third pixel opening on the array substrate;
the isolation openings comprise a first isolation opening and a second isolation opening, and depths of the first isolation opening and the second isolation opening are not equal in the direction perpendicular to the array substrate;
in an arrangement direction of the isolation openings, a size of an orthographic projection of the first isolation opening on the array substrate is not equal to a size of an orthographic projection of the second isolation opening on the array substrate;
the isolation openings further comprise a third isolation opening, and a depth of the third isolation opening is not equal to at least one of the depths of the first isolation opening and the second isolation opening in the direction perpendicular to the array substrate; and
in the arrangement direction of the isolation openings, the size of the orthographic projection of the first isolation opening on the array substrate is not equal to at least one of the size of the orthographic projection of the second isolation opening on the array substrate and a size of an orthographic projection of the third isolation opening on the array substrate.

16. The display panel according to claim 1, wherein the first openings comprise light-transmitting openings comprising a first light-transmitting opening and a second light-transmitting opening, and depths of the first light-transmitting opening and the second light-transmitting opening are not equal in a direction perpendicular to the array substrate;
in an arrangement direction of the light-transmitting openings, a size of an orthographic projection of the first light-transmitting opening on the array substrate is not equal to a size of an orthographic projection of the second light-transmitting opening on the array substrate;
the light-transmitting openings further comprise a third light-transmitting opening, and a depth of the third light-transmitting opening is not equal to at least one of the depths of the first light-transmitting opening and the second light-transmitting opening in the direction perpendicular to the array substrate; and
in the arrangement direction of the light-transmitting openings, the size of the orthographic projection of the first light-transmitting opening on the array substrate is not equal to at least one of the size of the orthographic projection of the second light-transmitting opening on the array substrate and a size of an orthographic projection of the third light-transmitting opening on the array substrate.

17. The display panel according to claim 12, wherein grooves are provided on the side of the pixel defining layer away from the array substrate, at least part of the groove being exposed into the first opening, and the first encapsulation layer extending into the groove.

18. The display panel according to claim 17, wherein a plurality of grooves are provided; orthographic projections of the grooves on the array substrate are within an orthographic projection of the first opening on the array substrate;
the orthographic projections of the grooves on the array substrate comprise a circular or polygonal shape;
widths of the orthographic projections of the grooves on the array substrate range from 2 m to 10 km; and
a spacing between the orthographic projections of adjacent grooves on the array substrate ranges from 2 m to 5 km.

19. A display panel, comprising:
a first active area and a second active area at least partially surrounding the first active area, and comprising:
an array substrate;
an isolation structure located on one side of the array substrate, at least part of the isolation structure enclosing first openings, and each of the first openings being located in the first active area; and
a first encapsulation layer at least partially filling the first opening and being in contact with a side of the at least part of the isolation structure close to the first opening;
wherein the first encapsulation layer comprises a first embedded structure, the first embedded structure being located in the first opening and being in contact with the isolation structure.

20. An electronic device, comprising:
a display panel, comprising:
an array substrate;
an isolation structure located on one side of the array substrate, at least part of the isolation structure enclosing first openings; and
a first encapsulation layer at least partially filling each of the first openings and being in contact with a side of the at least part of the isolation structure close to each of the first openings, the first encapsulation layer comprising a first embedded structure, and the first embedded structure being located in the first opening and being in contact with the isolation structure.
